(19) United States
(12) Patent Application Publication
(10) Pub. No.: US 2018/0240649 A1
(43) Pub. Date: Aug. 23, 2018

(54) SURFACE COATING FOR PLASMA PROCESSING CHAMBER COMPONENTS

(71) Applicant: Lam Research Corporation, Fremont, CA (US)

(72) Inventors: Jeremy SMITH, Alameda, CA (US); Eric PAPE, Campbell, CA (US); Devin RAMDUTT, Fremont, CA (US)

(21) Appl. No.: 15/436,414

(22) Filed: Feb. 17, 2017

(51) Int. Cl. H01J 37/32; C23C 28/04; C23C 28/00; C23C 16/40; C23C 16/02; C23C 16/455; C23C 18/12; C23C 18/04; C23C 4/134; C23C 4/11; B05D 1/02; B05D 1/18; B05D 1/28; B05D 3/00; B05D 1/36; C23C 4/18

(52) U.S. Cl. CPC H01J 37/32495; C23C 4/18; C23C 28/048; C23C 28/42; C23C 16/405; C23C 16/403; C23C 16/0272; C23C 16/45525; C23C 18/1254; C23C 18/1241; C23C 18/1245; C23C 18/1225; C23C 18/1216; C23C 18/04; C23C 4/134; C23C 4/11; B05D 1/02; B05D 1/18; B05D 1/28; B05D 3/002; B05D 3/007; H01J 37/32082; B05D 1/36; C23C 28/042

(57) ABSTRACT

A method for forming a protective coating for a component of plasma processing chamber is provided. A first ceramic coating is plasma sprayed over a surface of the component, wherein the first ceramic coating has pores. A sealant is applied over the first ceramic coating wherein sealant fills the pores of the first ceramic coating. The sealant is cured. A second ceramic coating is deposited over the first ceramic coating and sealant, wherein the second ceramic coating is thinner than and more dense than the first ceramic coating, wherein the depositing the second ceramic coating is by at least one of aerosol depositing or atomic layer deposition or sol-gel deposition.

### BACKGROUND OF THE INVENTION

The present invention relates to the manufacturing of semiconductor devices. More specifically, the invention relates to plasma chamber components used in manufacturing semiconductor devices.

During semiconductor wafer processing, plasma processing chambers are used to process semiconductor devices. Components of plasma processing chambers are subjected to plasmas, which may degrade the component.

### SUMMARY OF THE INVENTION

To achieve the foregoing and in accordance with the purpose of the present invention, a method for forming a protective coating for a component of plasma processing chamber is provided. A first ceramic coating is plasma sprayed over a surface of the component, wherein the first ceramic coating has pores. A sealant is applied over the first ceramic coating wherein sealant fills the pores of the first ceramic coating. The sealant is cured. A second ceramic coating is deposited over the first ceramic coating and sealant, wherein the second ceramic coating is thinner than and more dense than the first ceramic coating, wherein the depositing the second ceramic coating is by at least one of aerosol depositing or atomic layer deposition or sol-gel deposition.

In another manifestation, a component of a plasma processing chamber is provided. A component body is provided. A first ceramic coating covers a surface of the component body, wherein the first ceramic coating has pores. A cured sealant fills the pores of the first ceramic coating. A second ceramic coating is over the first ceramic coating and the cured sealant, wherein the second ceramic coating is less porous than the first ceramic coating, and wherein the second ceramic coating has been deposited by at least one of aerosol depositing or atomic layer deposition or sol-gel deposition.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of an embodiment of the invention.

FIGS. 2A-C are schematic views of a substrate processed according to an embodiment of the invention.

FIG. 3 is a schematic view of an etch reactor that may be used in an embodiment of the invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

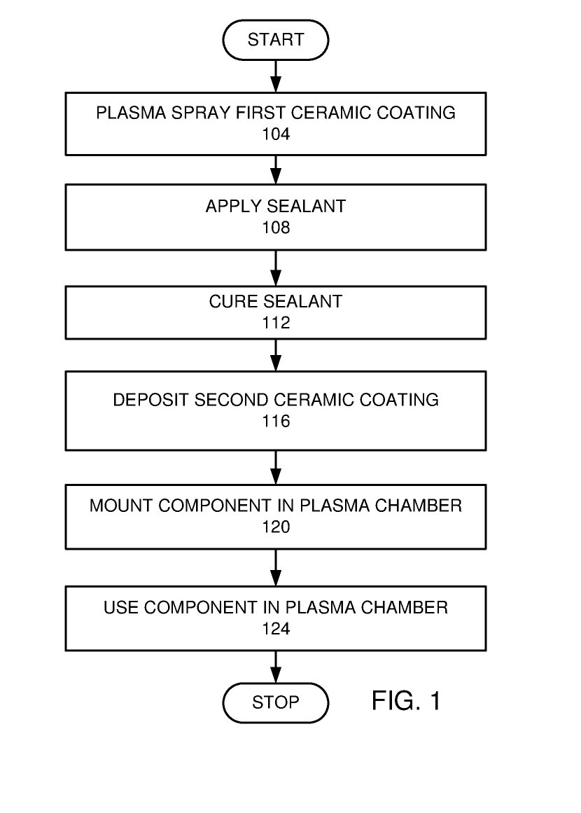

To facilitate understanding, FIG. 1 is a high level flow chart of a process used in an embodiment of the invention. A first ceramic coating is plasma sprayed on a surface of a component (step 104). A sealant is applied to the first ceramic coating (step 108). The sealant is cured (step 112). A second ceramic coating is deposited over the first ceramic coating and cured sealant, where the second ceramic coating is less porous than the first ceramic coating and where the second ceramic coating is deposited by aerosol depositing, atomic layer deposition, or sol-gel deposition (step 116). The component is mounted in a plasma processing chamber (step 120). The component is used in a plasma processing chamber (step 124).

### EXAMPLES

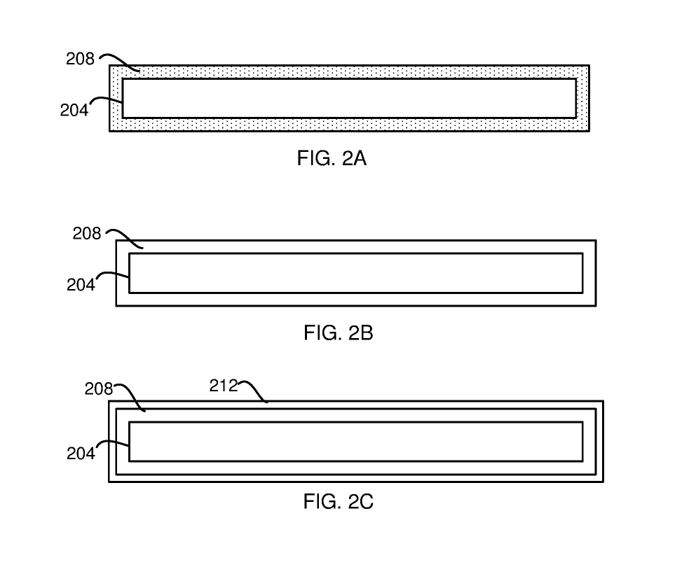

In an example of a preferred embodiment of the invention, a first ceramic coating is plasma sprayed on a surface of a component (step 104). FIG. 2A is a schematic cross-sectional view of a component 204 with a first ceramic coating 208 that has been plasma sprayed on all surfaces of the component 204. The first ceramic coating 208 has a porosity, which is indicated by the shading. In this embodiment the component is made of anodized aluminum. In other embodiments, the component is made of aluminum or ceramic. In this embodiment, the first ceramic coating 208 comprises alumina. In other embodiments, the first ceramic coating 208 comprises at least one of yttrium oxide (yttria), ceria, zirconia, or lanthanum oxide.

Plasma spraying is a type of thermal spraying in which a torch is formed by applying an electrical potential between two electrodes, leading to ionization of an accelerated gas (a plasma). Torches of this type can readily reach temperatures of thousands of degrees Celsius, liquefying high melting point materials such as ceramics. Particles of the desired material are injected into the jet, melted and then accelerated towards the substrate so that the molten or plasticized material coats the surface of the component and cool, forming a solid, conformal coating. Preferably, plasma spraying is used to deposit the first ceramic coating. These processes are distinct from vapor deposition processes, which use vaporized material instead of molten material. In this embodiment, the thickness of the ceramic coating is greater than 100 μm. An example of a recipe for plasma spraying the first ceramic coating (208) is as follows. A carrier gas is pushed through an arc cavity and out through a nozzle. In the cavity a cathode and anode comprise parts of the arc cavity, and are maintained at a large DC bias voltage, until the carrier gas begins to ionize, forming the plasma. The hot, ionized gas is in then pushed out through the nozzle forming the torch. Into the chamber near the nozzle is injected fluidized ceramic particles, tens of micrometers in size. These particles are heated by the hot, ionized gas in the plasma torch such that they exceed the melting temperature of the ceramic. The jet of plasma and melted ceramic is then aimed at a substrate. The particles impact the substrate, flattening and cooling to form a ceramic coating.

A sealant is applied to the first ceramic coating (step 108). In this example, the sealant is a polymer. More preferably, the sealant is a carbon based or silicon based polymer. The sealant may be applied by brush painting, spray painting, or dipping. In this embodiment, the sealant is polydimethylsiloxane, which is applied by painting with a brush. These application processes allow a thick enough deposition to allow the sealant to fill some of the pores of the first ceramic coating 208. In this embodiment, at least 90% of the pores are filled. In this embodiment, the sealant would be completely absorbed into the pores, so that in this embodiment, a completely continuous layer of sealant is not formed over the first ceramic coating.

FIG. 2B is a schematic cross-sectional view of a component 204 with the first ceramic coating 208 over a surface of the component 204 after the sealant has been applied. The sealant fills the pores, but does not form a continuous surface over the first ceramic coating 208. Since pores of the first ceramic coating 208 are filled, the shading is removed.

The sealant is cured (step 112). In this embodiment, the sealant is left at ambient temperature and pressure for 24 hours.

A second ceramic coating is deposited over the first ceramic coating and sealant, where the second ceramic coating is less porous than the first ceramic coating and where the second ceramic coating is deposited by at least one of aerosol depositing, atomic layer deposition, or so-gel deposition (step 116). In this embodiment, the second ceramic coating is deposited by aerosol deposition. Aerosol deposition is achieved by passing a carrier gas through a fluidized bed of ceramic particles. Driven by a pressure difference, the ceramic particles are accelerated through a nozzle, forming an aerosol jet at its outlet. The aerosol is then directed at the substrate, where it impacts the surface with high velocity. These particles break up into nanosized fragments, forming a coating. Optimization of carrier gas species, gas consumption, standoff distance and scan speed provides high quality coatings. FIG. 2C is a schematic cross-sectional view of a component 204 after the second ceramic coating 212 has been deposited.

The component is mounted in a plasma processing chamber (step 120). The plasma processing chamber is used to process a substrate (step 124), where a plasma is created within the chamber to process the substrate, such as etching the substrate, and the component is exposed to the plasma.

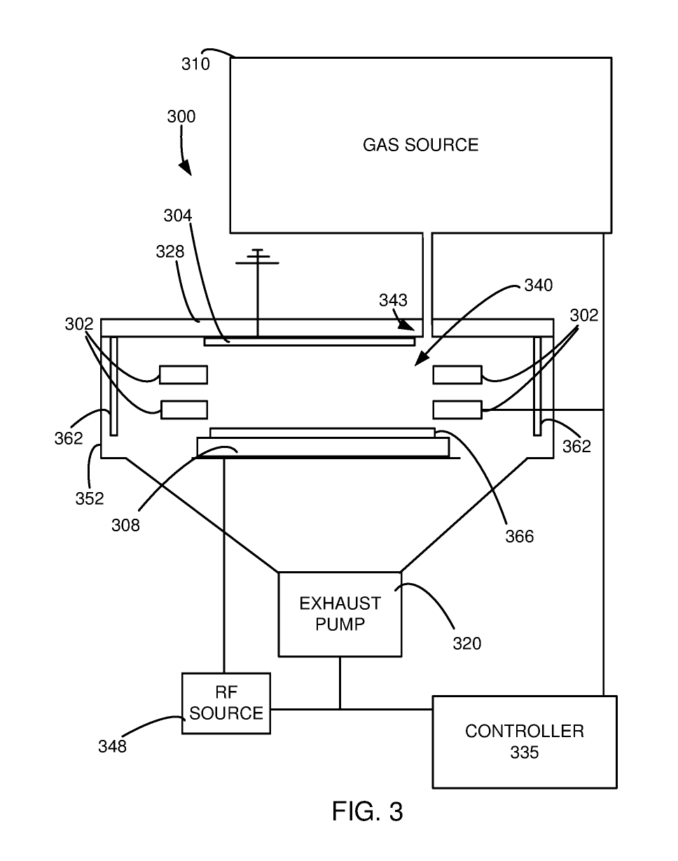

FIG. 3 is a schematic view of a plasma processing chamber 300 in which the component has been mounted. The plasma processing chamber 300 comprises confinement rings 302, an upper electrode 304, a lower electrode 308, a gas source 310, a liner 362, and an exhaust pump 320. In this example, the component is the liner 362. Within plasma processing chamber 300, a wafer 366 is positioned upon the lower electrode 308. The lower electrode 308 incorporates a suitable substrate chucking mechanism (e.g., electrostatic, mechanical clamping, or the like) for holding the wafer 366. The reactor top 328 incorporates the upper electrode 304 disposed immediately opposite the lower electrode 308. The upper electrode 304, lower electrode 308, and confinement rings 302 define the confined plasma volume 340.

Gas is supplied to the confined plasma volume 340 through a gas inlet 343 by the gas source 310 and is exhausted from the confined plasma volume 340 through the confinement rings 302 and an exhaust port by the exhaust pump 320. Besides helping to exhaust the gas, the exhaust pump 320 helps to regulate pressure. An RF source 348 is electrically connected to the lower electrode 308.

Chamber walls 352 surround the liner 362, confinement rings 302, the upper electrode 304, and the lower electrode 308. The liner 362 helps prevent gas or plasma that passes through the confinement rings 302 from contacting the chamber walls 352. Different combinations of connecting RF power to the electrode are possible. In a preferred embodiment, the 27 MHz, 60 MHz, and 2 MHz power sources make up the RF power source 348 connected to the lower electrode 308, and the upper electrode 304 is grounded. A controller 335 is controllably connected to the RF source 348, exhaust pump 320, and the gas source 310. The process chamber 300 may be a CCP (capacitive coupled plasma) reactor or an ICP (inductive coupled plasma) reactor, or other sources like surface wave, microwave, or electron cyclotron resonance ECR may be used.

Next generations of dielectric memory tools, operating at higher RF powers than prior tools have shown arcing failures between the ESC baseplate and various edge hardware on the chamber, such as edge rings, ground rings and coupling rings, accounting for >50% of all failures on next generation tools. To enable these tools to move from R&D into production, new technology will have to be developed to increase the stand-off voltage of the baseplate.

Without being bound by theory, it is believed that during plasma processing, chemical adsorbates within the pores of the spray coat provide a conductive pathway which can facilitate arcing. The sealant prevents this, leading to improvement in breakdown performance. It has been found that the application of sealant and curing alone does not protect the sealant, which thus degrades over time. Various embodiments provide a multi-layer structure, which combine the sealant with a layer to protect the sealant. The protective layer is provided through a relatively low temperature, high density coating technique to form plasma resistant coatings, which can retain their integrity over time and form a boundary layer to prevent the erosion of spray coat sealants. In addition, if the protective coating formed by the second ceramic coating is applied using the same or similar techniques as used for applying the first ceramic coating then the second coating would be ˜2% porous, and thus not prevent erosion. If the first ceramic coating was applied using at least one of aerosol depositing, atomic layer deposition, or so-gel deposition, it would take an unduly long time, and hence cost, to form a ceramic coating of greater than 100 μm. In addition, the use of a low temperature deposition of the second ceramic coating prevents the sealant from degrading. Preferably, the deposition of the second ceramic coating is at a temperature of less than 150° C.

The resulting coating is resistant to chemical degradation and arcing. As a result, plasma processing chambers with such components will have less defects, while decreasing failure rates of such systems and increasing the time between the replacements of various parts.

The first ceramic coating by a plasma spray may have a density of less than 98%, which means that the pores make up more than 2% of the coating, by volume. The second ceramic coating would have a density of greater than 99.9%, which means that the pores would make up less than 0.1% of the coating by volume. Preferably, the first ceramic coating has a thickness of at least 100 μm and less than 450 μm and the second ceramic coating has a thickness of no more than 10 μm. More preferably, the first ceramic coating has a thickness of at least 200 μm and the second ceramic coating has a thickness of no more than 5 μm. Most preferably, the first ceramic coating has a thickness of at least 300 μm and the second ceramic coating has a thickness of no more than 1 μm.

In other embodiments, the polymer sealant may be a silicon polymer or a carbon polymer. Such a sealant would be an elastomer that is able to penetrate the pores, when applied. In other embodiments, in addition to filling the pores, a continuous layer of the sealant may be formed over the first ceramic coating. The second ceramic coating is etch resistant, because of the ceramic material. In addition, the second ceramic coating is as non-porous as possible and has a high density, which thus requires the special deposition process.

In various embodiments, the component may be other parts of a plasma processing chamber, such as confinement rings, edge rings, the electrostatic chuck, ground rings, chamber liners, door liners, or other components. The plasma processing chamber may be a dielectric processing chamber or conductor processing chamber. In some embodiments one or more, but not all surfaces are coated.

While this invention has been described in terms of several preferred embodiments, there are alterations, permutations, modifications, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A method for forming a protective coating for a component of plasma processing chamber, comprising:
plasma spraying a first ceramic coating over a surface of the component, wherein the first ceramic coating has pores;
applying a sealant over the first ceramic coating wherein sealant fills the pores of the first ceramic coating;
curing the sealant; and
depositing a second ceramic coating over the first ceramic coating and sealant, wherein the second ceramic coating is thinner than and more dense than the first ceramic coating, wherein the depositing the second ceramic coating is by at least one of aerosol depositing or atomic layer deposition or sol-gel deposition.

2. The method, as recited in claim 1, wherein the sealant is a polymer.

3. The method, as recited in claim 1, wherein the sealant is a silicon based polymer.

4. The method, as recited in claim 3, wherein the first ceramic is one of alumina, yttria, ceria, zirconia, lanthanum oxide.

5. The method, as recited in claim 4, wherein the component comprises a body of at least one of aluminum, anodized aluminum, or ceramic.

6. The method, as recited in claim 5, wherein the applying sealant is by at least one of brush painting, spray painting, or dipping.

7. The method, as recited in claim 6, wherein the first ceramic coating is thicker than 100 microns and the second coating is thinner than 10 microns.

8. The method, as recited in claim 7, wherein a porosity of the first ceramic coating is greater than 2% and a porosity of the second ceramic coating is less than 0.1%.

9. The method, as recited in claim 8, wherein the sealant fills at least 90% of the pores of the first ceramic coating.

10. The method, as recited in claim 1, wherein the first ceramic coating is thicker than 100 microns and the second coating is thinner than 10 microns.

11. The method, as recited in claim 1, wherein a porosity of the first ceramic coating is greater than 2% and a porosity of the second ceramic coating is less than 0.1%.

12. The method, as recited in claim 11, wherein the sealant fills at least 90% of the pores of the first ceramic coating.

13. A component of a plasma processing chamber, comprising:
a component body;
a first ceramic coating covering a surface of the component body, wherein the first ceramic coating has pores;
a cured sealant filling the pores of the first ceramic coating; and
a second ceramic coating over the first ceramic coating and the cured sealant, wherein the second ceramic coating is less porous than the first ceramic coating, and wherein the second ceramic coating has been deposited by at least one of aerosol depositing or atomic layer deposition or sol-gel deposition.

14. The component, as recited in claim 13, wherein the sealant is a polymer.

15. The component, as recited in claim 13, wherein the first ceramic is one of alumina, yttria, ceria, zirconia, lanthanum oxide.

16. The component, as recited in claim 13, wherein the first ceramic coating is thicker than 100 microns and the second coating is thinner than 10 microns.

17. The component, as recited in claim 13, wherein a porosity of the first ceramic coating is greater than 2% and a porosity of the second ceramic coating is less than 0.1%.

18. The component, as recited in claim 13, wherein the sealant fills at least 90% of the pores of the first ceramic coating.
